(19) United States
(12) Patent Application Publication
(10) Pub. No.: US 2008/0292433 A1
(43) Pub. Date: Nov. 27, 2008

(54) BATCH EQUIPMENT ROBOTS AND METHODS OF ARRAY TO ARRAY WORK-PIECE TRANSFER FOR PHOTOVOLTAIC FACTORY

(76) Inventors: Robert Z. Bachrach, Burlingame, CA (US); Avi Tepman, Cupertino, CA (US); Alexander S. Polyak, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/747,391

(22) Filed: May 11, 2007

(51) Int. Cl. B65H 5/00

(52) U.S. Cl. 414/225.01; 901/31

(57) ABSTRACT

The present invention generally comprises equipment for an automated high volume batch work-piece manufacturing factory comprising work-piece handling and work-piece processing in a high productivity factory architecture capable of producing 1,000 or more work-piece an hour. The work-pieces may be presented to the equipment from a stacked supply to a parallel array. Additionally, the work-pieces may be transferred between manufacturing architectures by an array to array batch transfer. The work-pieces may be transferred within the manufacturing architecture in a parallel to parallel batch transfer operation. The robotic operations may be between robotic devices, between robotic devices and processing equipment, and within processing equipment.

### CROSS-REFERENCE TO RELATED APPLICATIONS

This application is related to U.S. patent application Ser. No. ______ (Attorney Docket No. APPM/011215/NBD/NBNP/KCHANG), filed on an even date herewith, U.S. patent application Ser. No. ______ (Attorney Docket No. APPM/011211/NBD/NBNP/KCHANG), filed on an even date herewith, U.S. patent application Ser. No. ______ (Attorney Docket No. APPM/011213/NBD/NBNP/KCHANG), filed on an even date herewith. Each of the aforementioned patent applications is hereby incorporated by reference.

### BACKGROUND OF THE INVENTION

1. Field of the Invention

Embodiments of the present invention generally describe automated equipment for batch array work-piece handling and processing in a high productivity factory architecture sized for producing 1,000 or more work-pieces an hour and as high as 40,000 per hour or more.

2. Description of the Related Art

Solar energy from the sun may be converted to electricity by utilizing a solar power technology called photovoltaics (PV) that uses solar cells tiled into modules. Solar cells produce direct current electricity from the sun's rays, which can be used to power equipment, to recharge batteries, or be converted to AC power for on-grid applications.

Increased productivity for manufacturing of PV cells and modules requires batch processing of multiple solar cell work-pieces simultaneously if supply is to meet customer demand. To produce the PV cells and modules, numerous processes may need to be performed upon a work-piece. The work-piece may thus need to be moved from one processing tool to another processing tool with an efficient method. A processing tool may comprise one or more chambers coupled together. For example, a processing tool that performs a vacuum based process may comprise one or more processing chambers and one or more load lock chambers coupled together. For a non-vacuum process such as metrology, the processing tool may comprise one or more metrology chambers.

Therefore, there is a need in the art for achieving high productivity and low cost automated robotic handling of a plurality of solar cell work-pieces from one robotic device to another connecting process chambers and process equipment.

### SUMMARY OF THE INVENTION

The present invention generally comprises equipment for an automated high volume work-piece manufacturing architecture comprising array work-piece handling and array work-piece processing organized in a regular fashion from a group of lines comprising parallel channels. For descriptive purposes, factory architecture supports a river of work-pieces comprising streams (lines) which are further sub-divided into one or more channels. Channels may operate in a continuous conveyor in some cases and in segmented piece-wise continuous batches in others. The batch array may be 1 or 2 dimensions, (i.e., 1×n or n×m work-pieces).

The work-pieces may be transported or presented to the equipment from a stacked supply to a parallel array of channels comprising a stream. Additionally, the work-pieces may be transferred between manufacturing architecture entities by an array to array batch transfer of channels. The work-pieces may be transferred within the manufacturing architecture in a parallel to parallel batch transfer operation as opposed to one work-piece at a time. The robotic operations on the streams of work-pieces may be between robotic devices, between robotic devices and processing equipment, and within processing equipment.

In one embodiment, an array to array work-piece transfer apparatus is disclosed. The apparatus comprises a robot coupled with a track extending between a plurality of processing tools, the robot having an axis of rotation, and an array end effector connected to the robot, the array end effector having a plurality of fingers extending therefrom with each finger having one or more slots for disposing a work-piece thereon, the array end effector is rotatable about the axis of rotation.

In another embodiment, a method of array to array transferring a plurality of work-pieces is disclosed. The method comprises extending an array end effector into a first processing tool, the array end effector having a plurality of slots for receiving the work-pieces, retrieving a plurality of work-pieces from the first processing tool onto the array end effector, each work-piece disposed in a separate slot on the array end effector, retracting the array end effector from the first processing tool, rotating the array end effector, and extending the array end effector into a second processing tool.

In yet another embodiment, a method of transferring a plurality of work-pieces from a first processing tool to a second processing tool is disclosed. The method comprises sliding the plurality of work-pieces from a processing chamber disposed within the first processing tool to a first load lock chamber disposed within the first processing tool, extending an array end effector into the first load lock chamber, the array end effector having a plurality of slots for receiving the work-pieces, retrieving a plurality of work-pieces from the first load lock chamber onto the array end effector, each work-piece disposed in a separate slot on the array end effector, retracting the array end effector from the first load lock chamber, rotating the array end effector, and extending the array end effector into a second load lock chamber disposed in the second processing tool.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention with particular one and two dimensional arrays and are therefore not to be considered limiting of its scope for the invention may admit to other equally effective embodiments.

FIG. 1 is a top view of a processing system according to an embodiment of the invention.

FIG. 2 is a side view of the processing system of FIG. 1.

FIG. 3A is a front view of the processing system of FIG. 1.

FIG. 3B is a perspective view of the processing system of FIG. 1 showing the linear array of work-pieces picked up from the stack.

FIGS. 4A-4D show a sequence of transferring a work-piece from a stack arrangement to a linear array arrangement according to an embodiment of the invention.

FIGS. 5A-5C show a sequence of gripping a work-piece by the processing system according to an embodiment of the invention.

FIG. 6 is a front view of the processing system of FIG. 1 having a plurality of work-pieces retrieved from a stack of work-pieces as a linear array.

FIG. 7 is a top view of the processing system of FIG. 1 having a plurality of work-pieces positioned over an array end effector on the insertion robot.

FIGS. 8A-8C show a sequence of disposing work-pieces onto the array end effector of the insertion robot according to an embodiment of the invention.

FIG. 9A is a front view of a plurality of work-pieces being disposed onto the array end effector of the insertion robot according to an embodiment of the invention.

FIG. 9B is a close up view of FIG. 9A.

FIG. 10 is a top view of the processing system of FIG. 1 having the array end effector of the insertion robot partially inserted into the processing tool.

FIG. 11 is top view of the processing system of FIG. 1 having the array end effector of the insertion robot inserted into the processing tool.

FIGS. 12A-12D show a sequence of disposing the work-pieces onto the work-piece receivers in the processing tool according to an embodiment of the invention.

FIG. 13 is a top view of the processing system of FIG. 1 having a plurality of work-pieces disposed within the processing tool and the array end effector of the insertion robot retracted to receive additional work-pieces.

FIG. 14 is a top view of a processing system according to another embodiment of the invention.

FIG. 15 is a top view of the array end effector of a transfer robot extending into the processing tool according to one embodiment of the invention.

FIG. 16 a top view of the array end effector of the transfer robot of FIG. 15 having retrieved a plurality of work-pieces from the processing tool.

FIG. 17 is a top view of the array end effector of the transfer robot of FIG. 16 rotating.

FIG. 18 is a top view of the array end effector of the transfer robot of FIG. 17 rotated to insert the work-pieces into another processing tool.

FIG. 19 is a top view of the array end effector of the transfer robot of FIG. 18 inserted into another processing tool.

FIG. 20 is a top view of the processing system of FIG. 14 having the plurality of work-pieces disposed within another processing tool.

FIG. 21 is a top view of the array end effector of a work-piece unloading robot extending into a processing tool to retrieve a plurality of work-pieces.

FIG. 22 is a top view of the array end effector of the work-piece unloading robot unloading a plurality of work-pieces.

FIGS. 23A and 23B are schematic views of a plurality of processing tools coupled together.

FIG. 24 is a top view of a parallel to parallel transfer arrangement for a processing tool according to one embodiment of the invention.

FIG. 25 is a top view of the processing tool of FIG. 24 with an array end effector extending into the processing chamber.

FIG. 26 is a cross sectional view of FIG. 25.

FIG. 27 is a cross sectional view of the processing tool of FIG. 24 with the array end effector extending into the processing chamber.

FIG. 28 is a cross sectional view of the processing tool of FIG. 24 with the work-pieces received on lift pins in the processing chamber.

FIG. 29 is a cross sectional view of the processing tool of FIG. 24 with another array end effector entered into the processing chamber to retrieve the work-pieces.

FIG. 30 is a top view of the processing tool of FIG. 24 with a plurality of work-pieces inserted into the processing chamber.

FIG. 31 is a top view of the processing tool of FIG. 24 with a plurality of work-pieces retrieved from the processing chamber into the unload lock chamber.

FIG. 32 is a schematic view of a FAB within which photovoltaic work-pieces may be processed.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

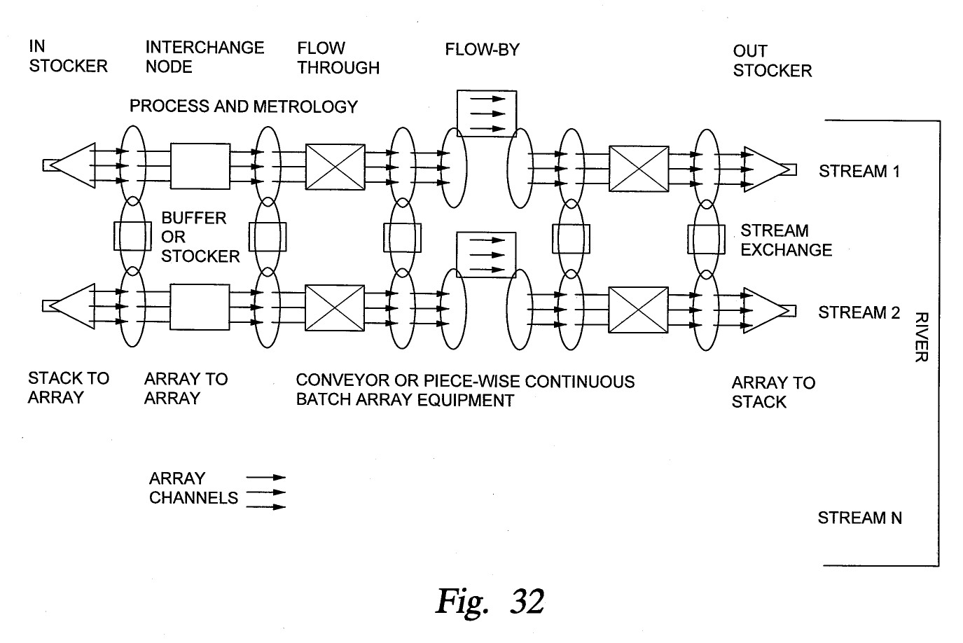

The present invention generally comprises equipment for an automated high volume work-piece manufacturing architecture comprising work-piece handling and work-piece processing. FIG. 32 shows a schematic view of a FAB, sometimes referred to as a factory, within which photovoltaic work-pieces may be processed by introducing the work-pieces to a processing line. Processing lines may alternatively be referred to as streams. A plurality of identical processing lines within a FAB may be referred to as a river. The work-pieces may initially be stacked one on top of another, but transferred from the stacked arrangement to an array arrangement before introduction to the processing line. The individual arrays within the processing lines or streams, arranged adjacent to each other as shown by the arrows, may be referred to as array channels.

The work-pieces may be transferred between processing tools along a processing line or stream by an array to array transfer whereby an array of work-pieces may be transferred from one processing tool to another processing tool as an array rather than individually transferring the work-pieces one at a time. The various processing tools may include one or more metrology tools. The processing tool may be arranged in a flow through manner whereby the processing tools are arranged in a linear fashion, a flow-by arrangement whereby the processing tools are arranged in a non-linear fashion, or a combination of flow through and flow-by arrangements. The work-pieces may be transferred within the manufacturing architecture in a parallel to parallel batch transfer operation. The robotic operations for the transfers may be between robotic devices, between robotic devices and processing equipment, and within processing equipment.

Whenever a processing tool within any processing line is shut-down, rather than shut-down the entire processing line containing the shut-down processing tool, work-pieces may be routed around the shut-down processing tool by transferring the work-pieces to an adjacent processing line within the FAB at an interchange node. The plurality of work-pieces may be transferred to other processing lines or streams through buffer or stocker stations. A buffer station may permit transfer between adjacent processing lines or streams while a stocker station may permit transfer between non-adjacent processing lines or streams. The buffer stations may additionally be used to store work-pieces while waiting to be disposed into the next processing tool. At a location after the shut-down processing tool, the work-pieces may be transferred back to the processing line containing the shut-down processing tool through buffer or stocker stations. After the processing within the processing line or stream is completed, the work-pieces may be transferred from an array arrangement back to a stack arrangement. During the time period that the processing tool is shut-down, the other processing lines within the FAB may increase their throughput in order to maintain a substantially constant optimum throughput for the FAB over a given period of time. As used throughout this application, the term array, sometimes referred to as a matrix, may be understood to encompass an arrangement of work-pieces in an n×m manner where n≧1 and m≧1 where at least one or n or m is greater than 1. An array is a set of photovoltaic work-pieces laid out in tabular form, often in rows, columns, or rows and columns. A batch array is a group of arrays. Batch array transferring refers to transferring a group of arrays.

While the description herein may comprise a discussion of batch work-piece transfer within processing tools, array to array transfer of work-pieces between tools, and stack to array work-piece transferring, the claims that follow may be directed to array to array transfer of work-pieces between processing tools.

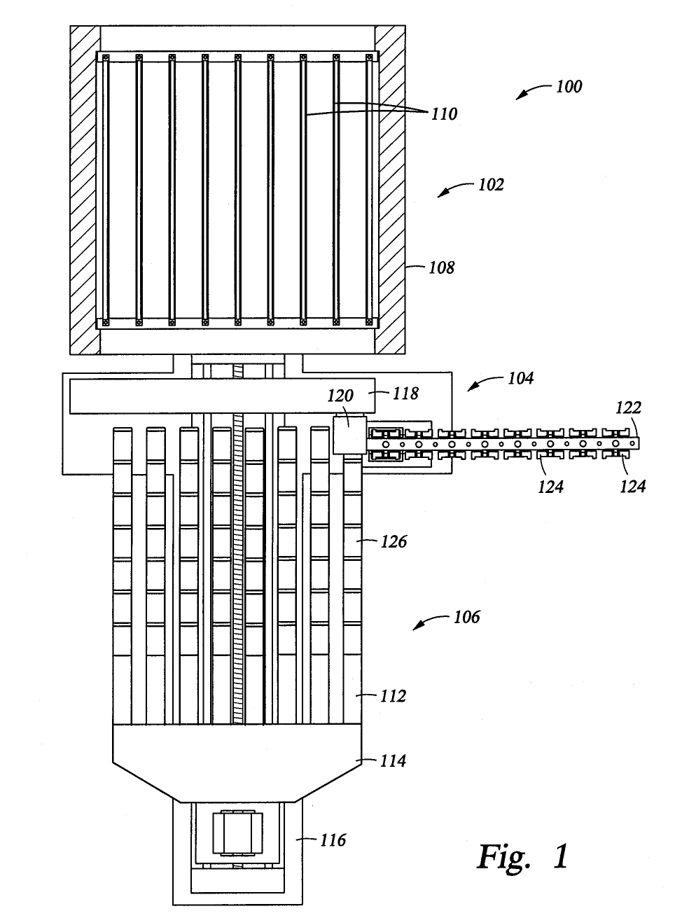

FIG. 1 is a top view of a processing system 100 according to an embodiment of the invention. The processing system 100 may include a processing tool 102, a stack-to-parallel loader robot 104, and an insertion robot 106. The processing tool 102 may comprise a plurality of walls 108 that may bound a processing space for the processing tool 102. While only shown as one chamber, it is to be understood that the processing tool 102 refers to one or more chambers coupled together to accomplish one or more processing steps in a manufacturing process. The one or more chambers may comprise load lock chambers, processing chambers, metrology chambers, etc. The processing chambers may comprise chemical vapor deposition (CVD) chambers, physical vapor deposition (PVD) chambers, etching chambers, cleaning chambers, etc. The work-pieces, during processing, may be disposed on one or more receivers 110 within the processing tool 102. The receivers 110 may comprise one or more lift pins or a plurality of rods that span the chamber. In one embodiment, the work-pieces may comprise solar cell work-pieces.

The work-pieces may be inserted into the processing tool 102 by an insertion robot 106. The insertion robot 106 may be movable along a track 116 between a position where work-pieces may be disposed onto the insertion robot 106 and a position for disposing the work-pieces into the processing chamber 102. The insertion robot 106 may comprise an array end effector having one or more fingers 112 that extend from a palm portion 114. An end effector may comprise a device at the end of a robotic arm, designed to interact with an environment. The exact nature of the end effector depends on the application of the robot. The end effector is, in essence, the “hand” connected to a robot's arm which may retain the photovoltaic work-pieces. An array end effector is an end effector capable of retaining one or more arrays of photovoltaic work-pieces as opposed to a single work-piece. Each finger 112 may comprise one or more slots 126 for holding one or more work-pieces. In one embodiment, the array end effector may comprise eight fingers 112 with each finger 112 comprising eight slots 126. The slots 126 may be arranged on the array end effector to have a plurality of rows of slots 126 along the plurality of fingers 112. While the invention is described below within regards to eight fingers 112 having eight slots 125, it is to be understood that more or less fingers 112 having more or less slots 126 may be utilized depending upon the desired batch work-piece size and required equipment throughput.

The work-pieces may be disposed onto the array end effector by a stack-to-parallel loader robot 104. The loader robot 104 may comprise one or more work-piece retrievers 124 disposed on a bar 122. In one embodiment, the one or more work-piece retrievers 124 may comprise eight work-piece retrievers 124. The bar 122 may be movable within a plane perpendicular to track 116 upon which the insertion robot 106 may move. The bar 122 may extend from a movement mechanism 120 that moves along a track 118 for positioning the work-piece retrievers 124 selectively over the work-pieces and the slots 126 on the fingers 112 of the array end effector.

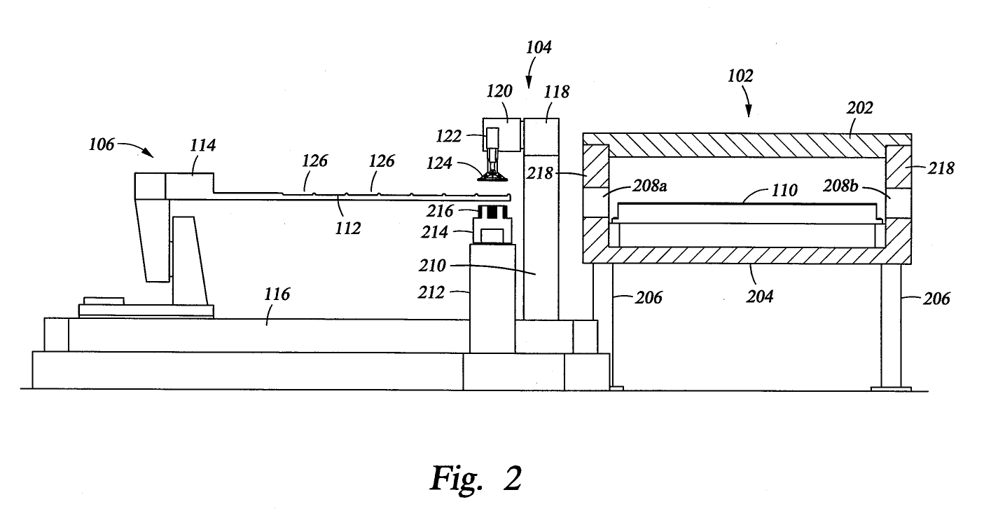

FIG. 2 is a side view of the processing system of FIG. 1. As may be seen from FIG. 2, the processing tool 102 may comprise a top 202 and bottom 204. Sidewalls 218 that extend within a plane parallel to the track 118 upon which the bar 122 moves may extend between the top 202 and bottom 204 of the processing tool 102. The sidewalls 218 may each comprise an opening 208a, 208b. The array end effector of the insertion robot 106 may enter the processing tool 102 through the opening 208a to dispose the work-pieces within the processing tool 102. Similarly, another robot (not shown) may enter the processing tool 102 from the opening 208b and retrieve the work-pieces after processing. The processing tool 102 may be elevated from the ground by a plurality of legs 206.

The track 118 upon which the movement mechanism 120 of the stack-to-parallel loader robot 104 moves may be positioned above the fingers 112 of the array end effector of the insertion robot 106 by a post 210. The movement mechanism 120 may move the bar 122 upon which the one or more work-piece retrievers 124 are disposed over the fingers 112 of the array end effector as well as a stack of work-pieces 216 disposed in a work-piece dispenser 214 disposed on top of a post 212. The stack of work-pieces 216 in the work-piece dispenser 214 saves valuable storage space because the work-pieces are vertically stacked within the work-piece dispenser 214.

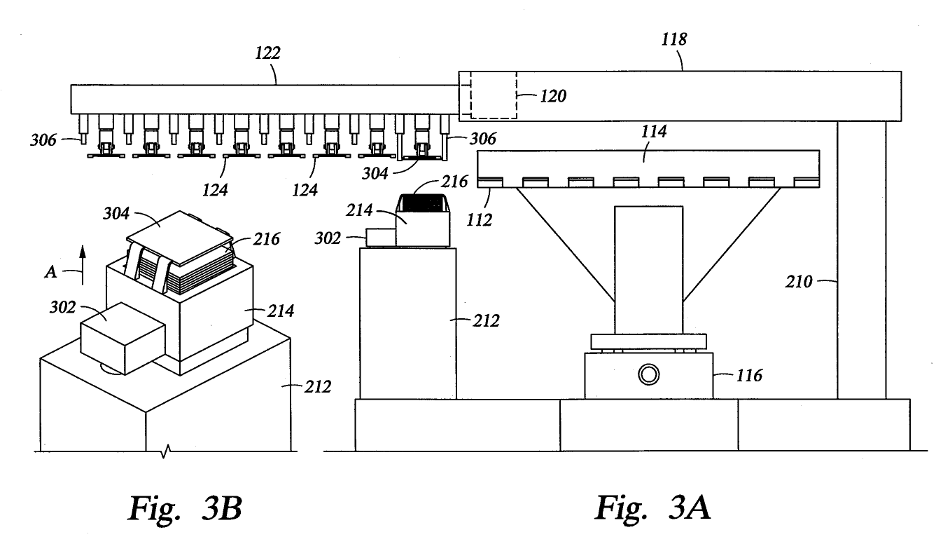

During processing, the movement mechanism 120 positions the appropriate work-piece retriever 124 over the stack of work-pieces 216 as shown in FIG. 3A. An actuator 302 then moves the work-piece dispenser 214 vertically, as represented by arrow “A” shown in FIG. 3B, so that a work-piece 304 may be retrieved by the work-piece retriever 124. The work-piece 304, once retrieved by the work-piece retriever 124, may additionally be supported on the side by a side support 306 disposed adjacent the work-piece retrievers 124. The side supports 306 may align the work-piece 304 within the work-piece retriever 124.

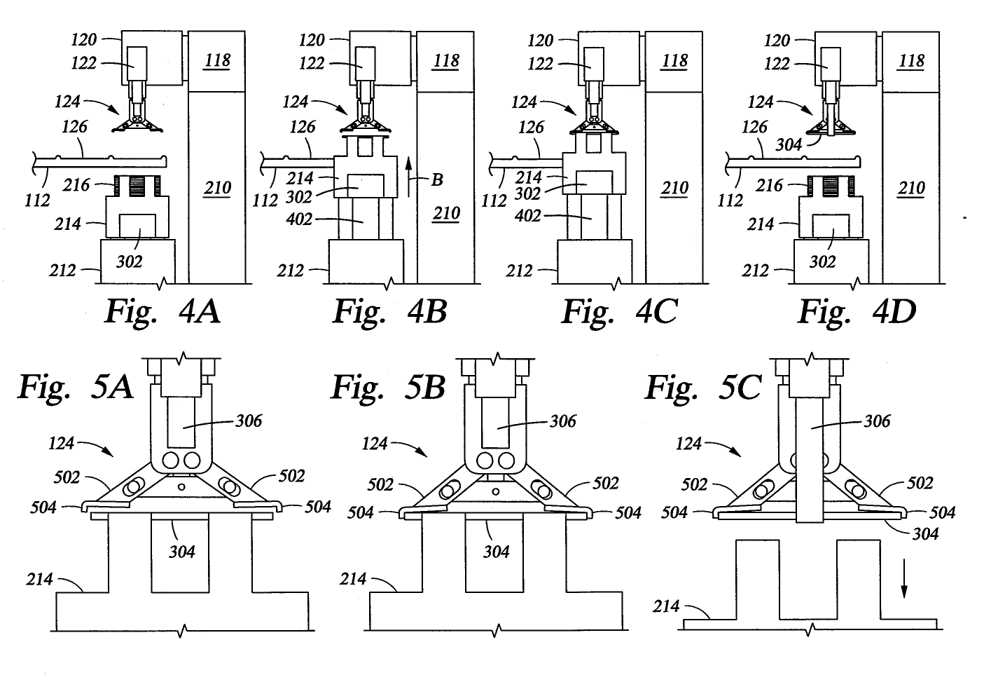

FIGS. 4A-4D show a sequence of transferring a work-piece 304 from a stack arrangement to a parallel arrangement according to an embodiment of the invention. A work-piece retriever 124 is initially disposed over a stack of work-pieces 216 disposed on the work-piece dispenser 214 (FIG. 4A). Although one retriever is depicted, more than one can operate at the same time. The work-piece dispenser 214 may then be vertically actuated as shown by arrow “B” by the actuator 302 (FIG. 4B). The work-piece dispenser 214 may extend upon one or more legs 402. The work-piece retriever 124 may then grip the work-piece 304 (FIG. 4C). Following work-piece 304 retrieval by the work-piece retriever 124, the work-piece dispenser 214 may lower down to the original position by the actuator 302 (FIG. 4D).

FIGS. 5A-5C show a sequence of gripping a work-piece by the work-piece retrieval system according to an embodiment of the invention. The work-piece retriever 124 may comprise one or more arms 502 which extend out beyond the work-piece 304. One or more grippers 504 may be disposed on the end of the arms 502 (FIG. 5A). Once the work-piece dispenser 214 is raised to meet the work-piece retriever 124, the arms 502 close around the work-piece 304 enabling the grippers 504 to grip the work-piece 304 (FIG. 5B). Once the work-piece 304 is effectively gripped, the work-piece dispenser 214 retracts to the original, lowered position (FIG. 5C). Simultaneous with the work-piece dispenser 214 retraction, the side supports 306 adjacent the work-piece retriever 124, lower to support/align the work-piece 304 from the side.

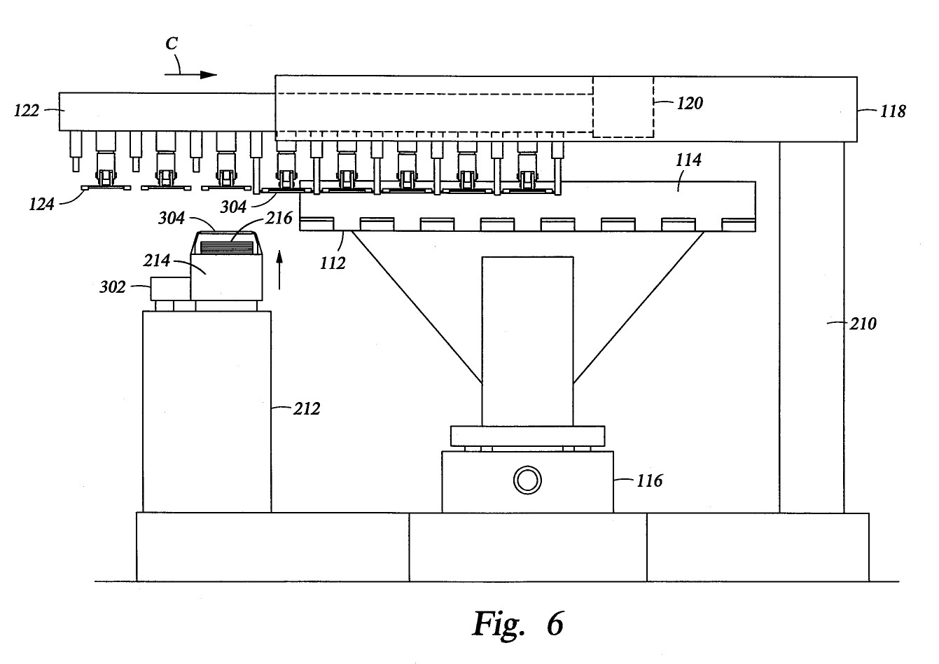

After each work-piece 304 is retrieved, the movement mechanism 120 moves the bar 122 along the track 118 as shown by arrow “C” (FIG. 6). The work-piece retrievers 124 are each positioned over the work-piece dispenser 214 where each work-piece retriever 124 may retrieve a work-piece 304. As the work-piece retrievers 124 are linearly actuated with the bar 122 by the movement mechanism 120, the work-piece retrievers 124 begin to be positioned over the fingers 112 of the array end effector.

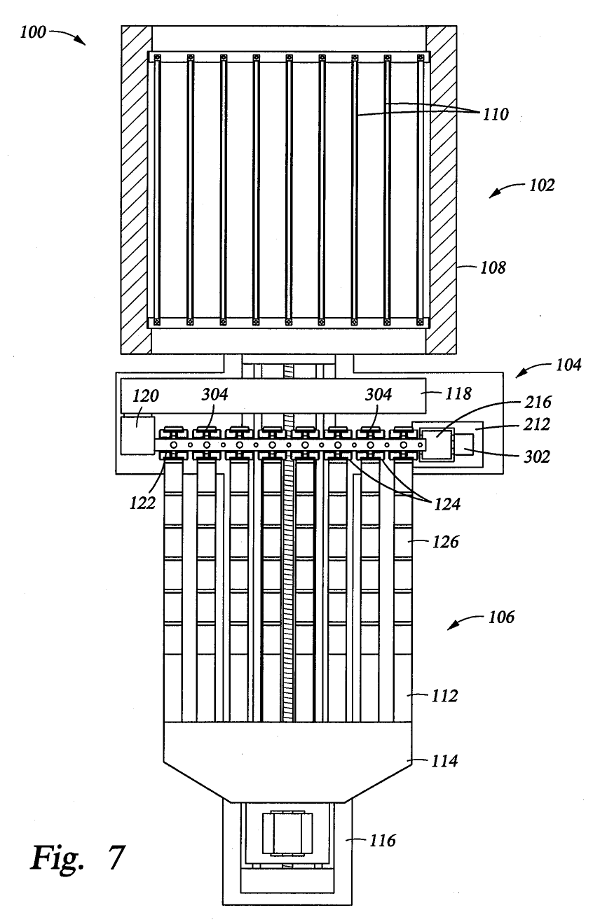

Once each work-piece retriever 124 has retrieved a work-piece 304 from the work-piece dispenser 214, the movement mechanism 120 disposes each work-piece retriever 124 over a corresponding slot 126 on a finger 112 of the array end effector (FIG. 7). The work-pieces 304 are then disposed within the slots 126 of the fingers 112.

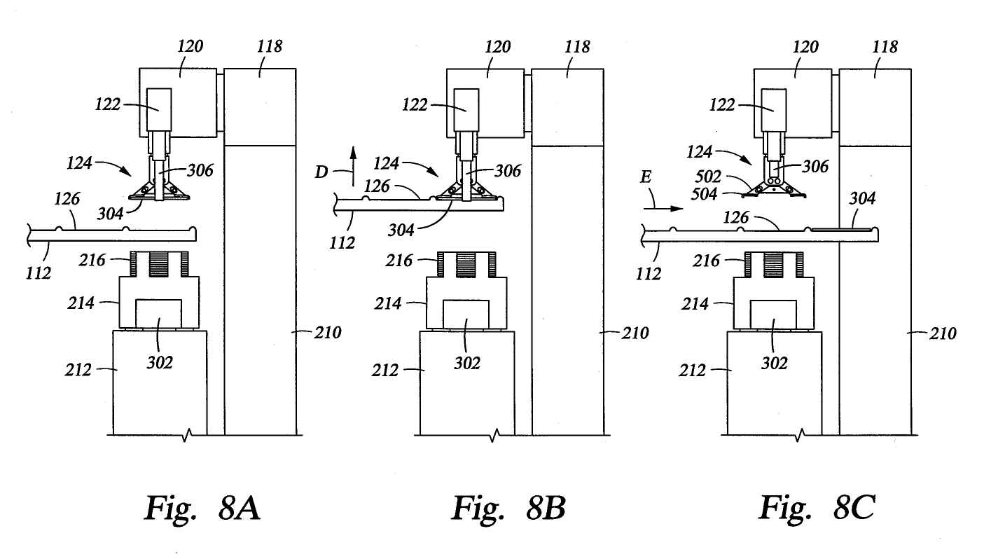

FIGS. 8A-8C show a sequence of disposing work-pieces onto the array end effector of the insertion robot according to an embodiment of the invention. The work-pieces 304 on the work-piece retrievers 124 are initially disposed over the fingers 112 of the array end effector by the movement mechanism 120 (FIG. 8A). The fingers 112, and correspondingly the entire array end effector, elevates as shown by arrow “D” to engage the work-piece retrievers 124 (FIG. 8B). The grippers 504 on the end of the arms 502 of the work-piece retrievers 124 then release the work-pieces 304 into the slots 126. As the work-piece retrievers 124 release the work-pieces 304, the side supports 306 raise to their original position. The fingers 112, and correspondingly the entire array end effector, lower. After the fingers 112 lower, the insertion robot 106 then advances the array end effector as shown by arrow “E” so that the next row of slots 126 are disposed below the work-piece retrievers 124.

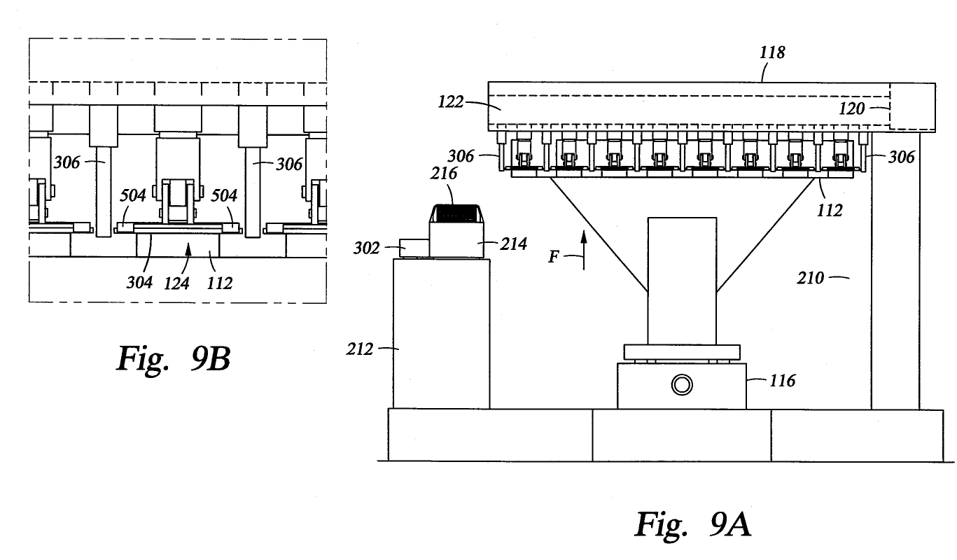

FIG. 9A is a front view of a plurality of work-pieces 304 being disposed onto the array end effector of the insertion robot 106 according to an embodiment of the invention. As may be seen from FIG. 9A, the insertion robot 106 moves the array end effector upward as shown by arrow “F” to meet the work-piece retrievers 124. Each work-piece retriever 124 is disposed over a corresponding slot 126 of a corresponding finger 112. FIG. 9B is a close up view of FIG. 9A. The work-pieces 304 are released into the slots 126 disposed on the fingers 112.

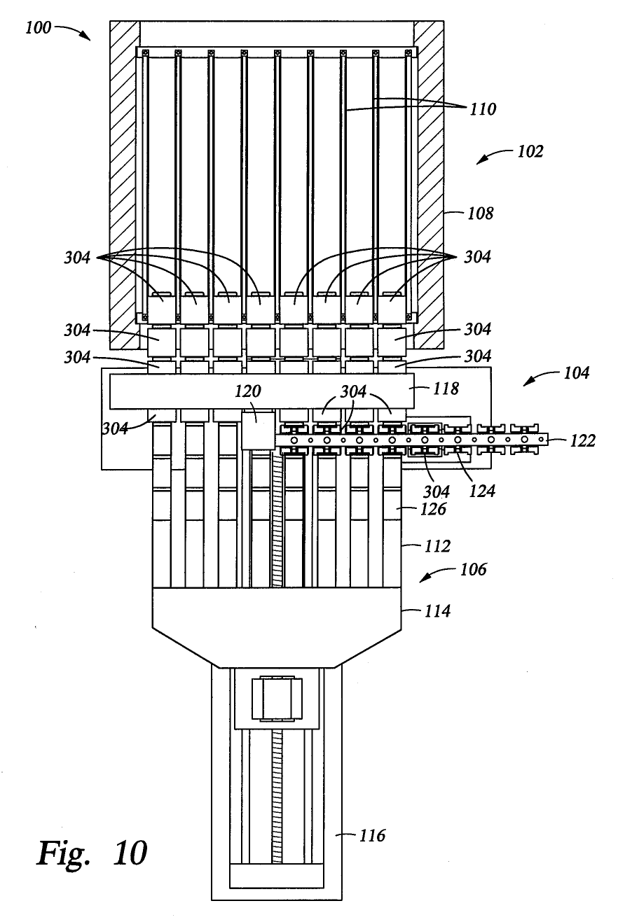

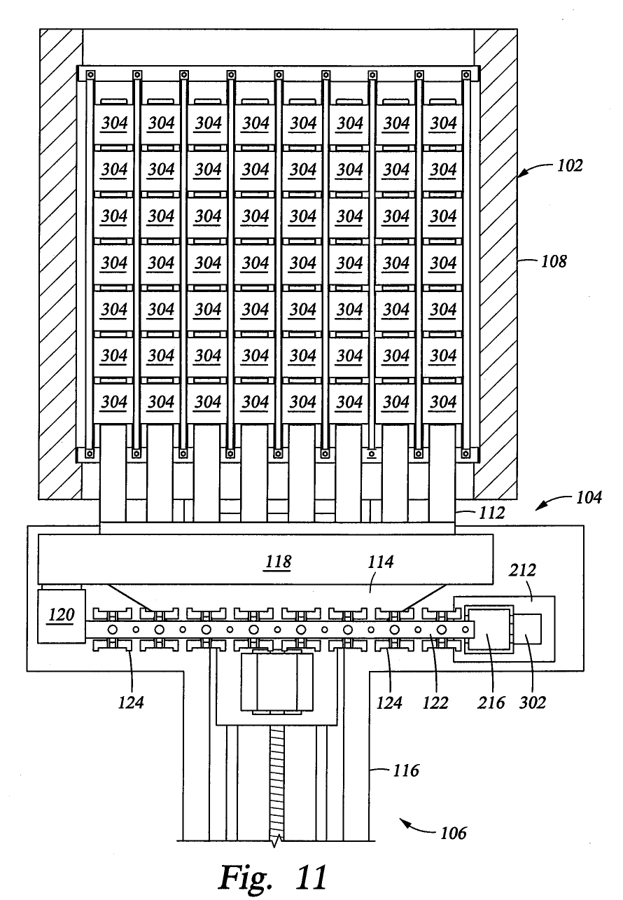

As more and more work-pieces 304 are retrieved by the work-piece retrievers 124 on the stack-to-parallel loader robot 104, the array end effector of the insertion robot 106 begins to enter into the processing tool 102 through the opening 208a as shown in FIG. 10. As the array end effector begins to enter the processing tool 102, the work-pieces 304 are disposed above the one or more work-piece receivers 110 disposed within the processing tool 102.

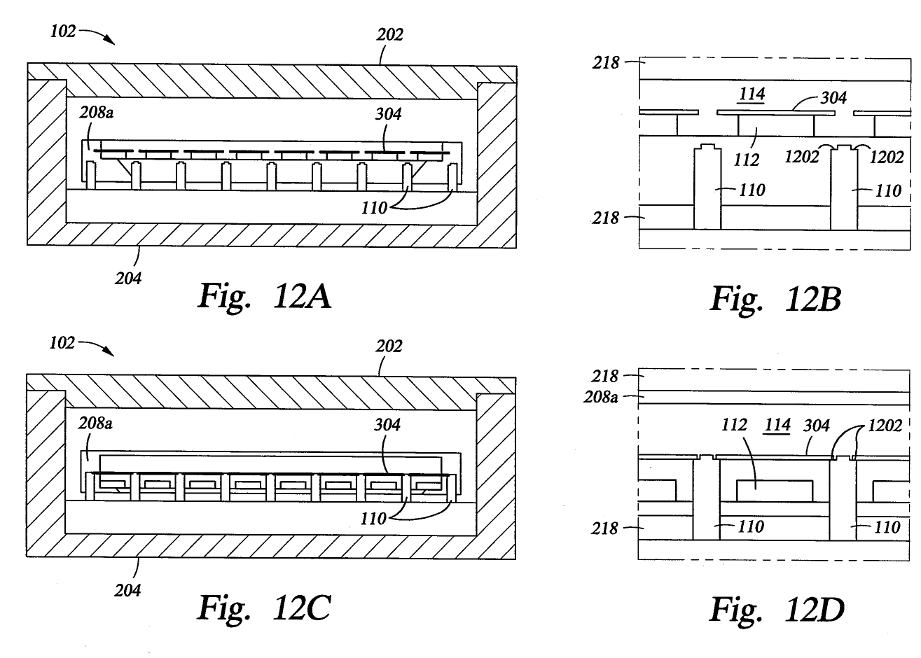

After all of the work-pieces have been disposed into the processing tool 102 by the insertion robot 106 (FIG. 11), the work-pieces may then be disposed onto the work-piece receivers 110 disposed within the processing tool 102. FIGS. 12A-12D show a sequence of disposing the work-pieces onto the work-piece receivers in the processing tool 102 according to an embodiment of the invention. The work-pieces 304 disposed on the fingers 112 are positioned within the processing tool 102 above the plurality of work-piece receivers 110. FIG. 12A is a cross sectional view of the processing tool 102 having the fingers 112 and work-pieces 304 disposed therein. FIG. 12B shows a close-up view of the fingers 112 and work-pieces 304 within the processing tool 102 above the work-piece receivers 110. The work-piece receivers 110 each have a notch 1202 within which the work-pieces 304 may rest once disposed on the work-piece receivers 110. The fingers 112 then lower and the work-pieces 304 are supported from on their edges by the work-piece receivers 110 within the processing tool 102 (FIG. 12C). As may be seen in FIG. 12D, when the fingers 112 are lowered, each work-piece rests on the work-piece receivers 110. The edges of the work-pieces 304 may be disposed within the notches 1202 of the work-piece receivers 110.

Once the work-pieces 304 have been disposed within the processing tool 102, the array end effector may be retracted by the insertion robot 106 along the track 116 from the processing tool 102. While the work-pieces 304 are processed within the processing tool 102, additional work-pieces 304 may be disposed onto the array end effector of the insertion robot 102 by the stack-to-parallel loader robot 104. Following the completion of processing, the work-pieces 304 may be removed from the processing tool 102 through the slot 208b by a robot having a similar arrangement as the insertion robot 106. The work-pieces may be unloaded from the removing robot by a parallel-to-stack unloading robot similar to the stack-to-parallel loader robot 104. In one embodiment, the work-pieces 304 may be removed from the processing tool 102 after processing by the array end effector of the insertion robot 106 and unloaded from the array end effector of the insertion robot 106 by the stack-to-parallel loader robot 104.

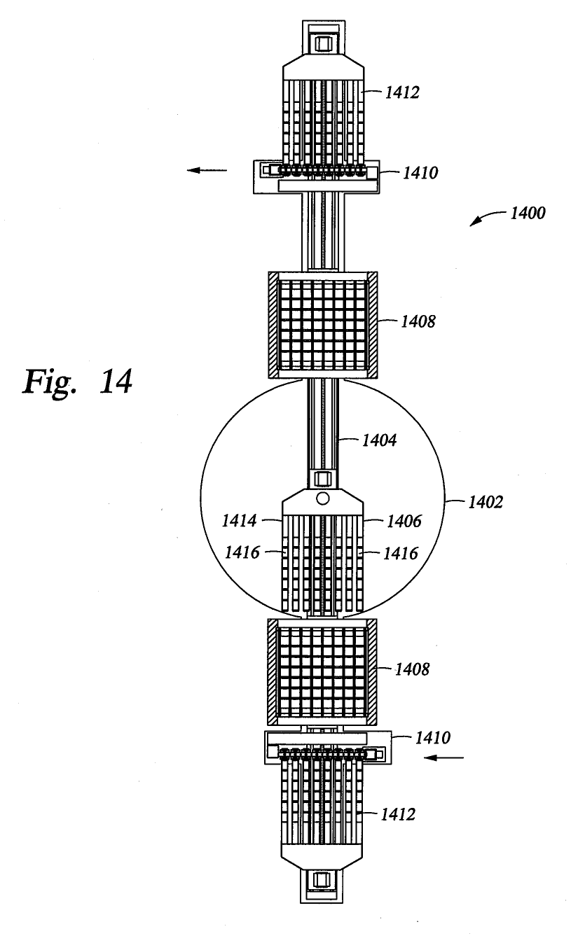

FIG. 14 is a top view of a processing system 1400 according to another embodiment of the invention. The processing system 1400 includes a plurality of processing tools 1408. A stack-to-parallel robot 1410 may load/unload work-pieces from a robot 1412 having an array end effector that inserts/removes a plurality of work-pieces from the processing tools 1408. A transfer robot 1402 having an array end effector 1406 may retrieve a plurality of work-pieces from a processing tool 1408 and transfer the work-pieces 1408 to another processing tool 1408. The transfer robot 1402 may move the array end effector 1406 between processing tools 1408 on a track 1404. The array end effector 1406 may include a plurality of fingers 1414. One or more slots 1416 may be present on each finger 1414. One or more work-pieces may be disposed within the slots 1416 during work-piece transfer.

It should be understood that while only two processing tools 1408 have been exemplified, more processing tools 1408 are possible. Additionally, each processing tool 1408 refers to one or more chambers coupled together to accomplish one or more processing steps in a manufacturing process. The one or more chambers may comprise load lock chambers, processing chambers, metrology chambers, etc. The processing chambers may comprise CVD chambers, PVD chambers, etching chambers, cleaning chambers, etc.

The transfer robot 1402 may be surrounded by as many processing tools 1408 as will fit within the processing space. When more than two processing tools 1408 are present, it may be necessary to provide branches in the track 1404 to permit the array end effector 1406 of the transfer robot 1402 to access the additional processing tools 1408.

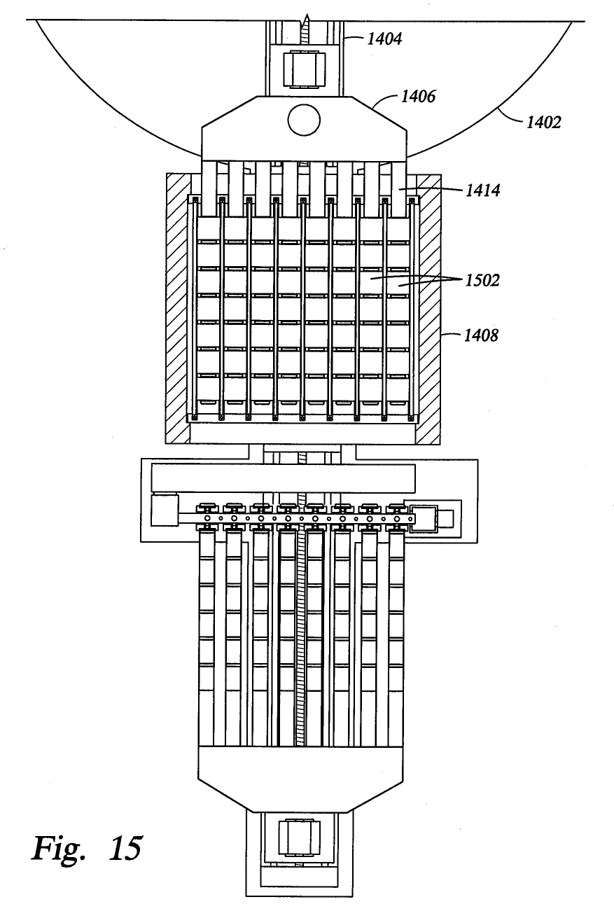

As may be seen in FIG. 15, the array end effector 1406 of the transfer robot 1402 extends into a processing tool 1408. The transfer robot 1402 moves the array end effector 1406 along the track 1404 such that the fingers 1414 of the array end effector 1406 extend into the processing tool 1408 under the plurality of work-pieces 1502 disposed in the processing tool 1408. A slot 1416 on the fingers 1414 may be positioned underneath each work-piece 1502 disposed in the processing tool 1408.

The array end effector 1406 may retrieve the work-pieces in a manner similar to that discussed above in relation to FIGS. 12A-12D except that the sequence of retrieving the work-pieces 1502 may occur in the opposite order as compared to inserting the work-pieces. It should be noted that the transfer robot 1402 enables array to array transfer of the work-pieces 1502 between processing tools 1408. Array to array transfer means maintaining the work-pieces within substantially the same plane while transferring the work-pieces from one processing tool to another processing tool.

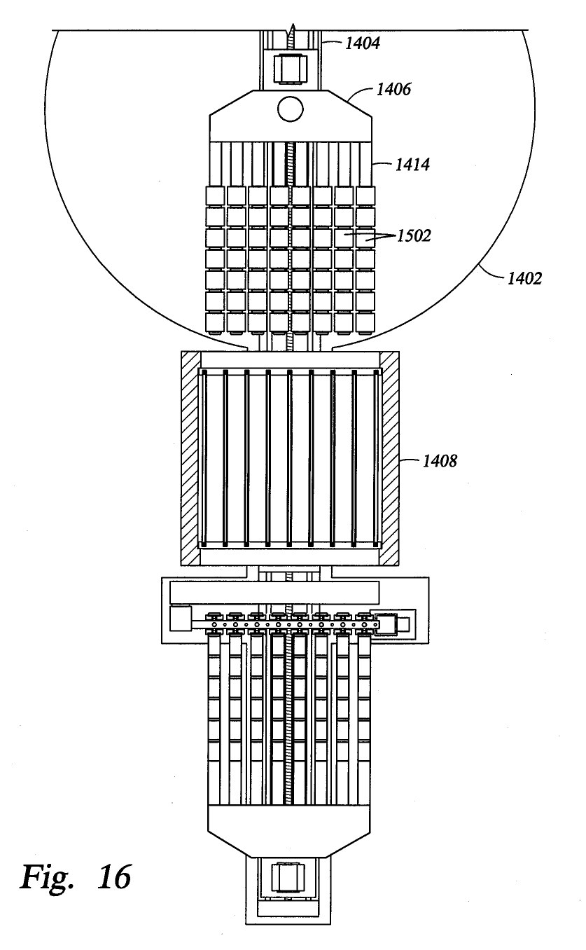

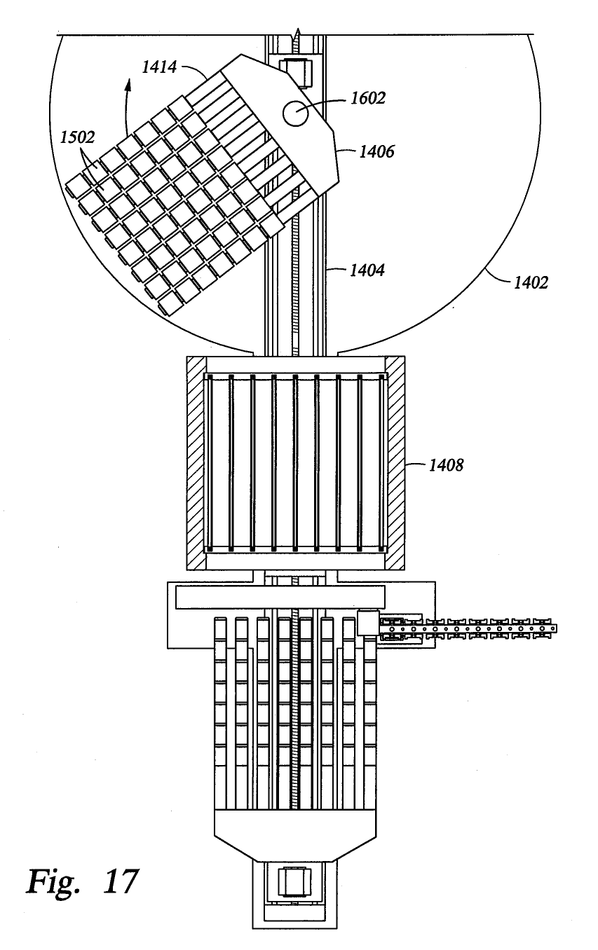

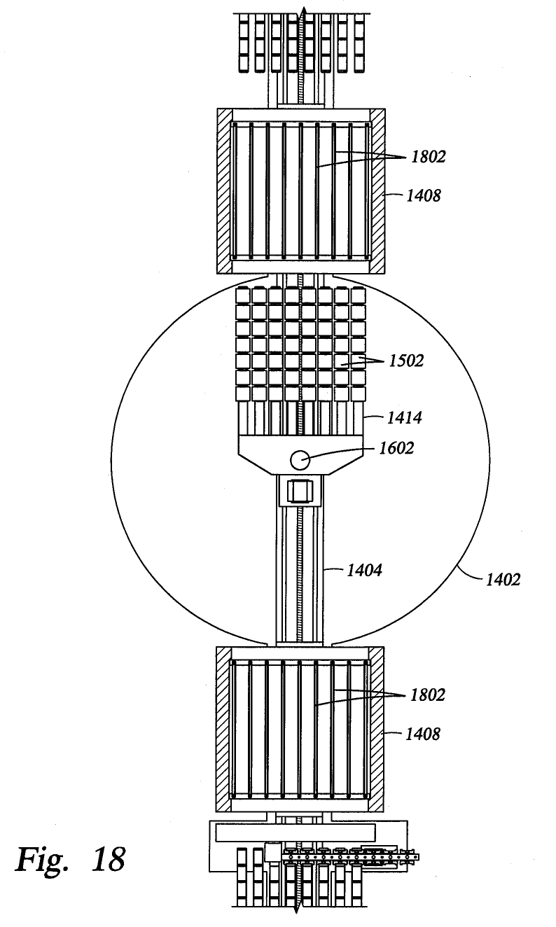

Once the array end effector 1406 has retrieved the work-pieces 1502, the robot 1402 retracts the array end effector 1406 from the processing tool 1408 as shown in FIG. 16. To dispose the work-pieces 1502 into another processing tool 1408, the transfer robot 1402 may need to rotate the array end effector 1406 as shown by arrow “G” about an axis of rotation 1702 as shown in FIG. 17. In one embodiment, the array end effector 1406 may rotate about 180 degrees to a position for inserting the work-pieces into the processing tool 1408 as shown in FIG. 18. It is to be understood that the amount that the array end effector 1406 may need to rotate will depend upon the location of the next processing tool 1408. Upon insertion, the work-pieces 1502 may be disposed onto a plurality of work-piece receivers 1802.

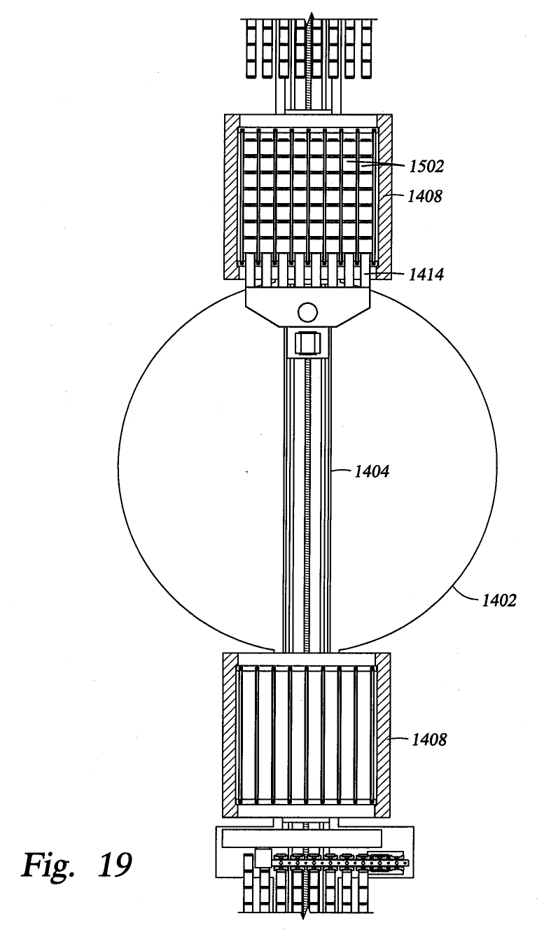

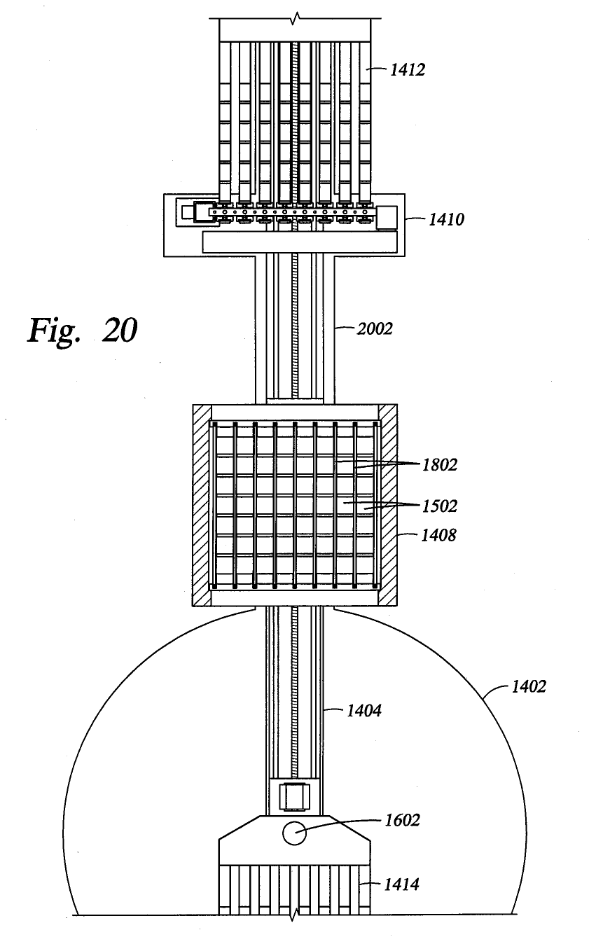

Once the array end effector 1406 is in position, the transfer robot 1402 moves the array end effector 1406 along the track 1404 to extend the fingers 1414 into the processing tool 1408 as shown in FIG. 19. The work-pieces 1502 may be disposed into the processing tool 1408 for processing. Once the work-pieces 1502 are disposed in the processing tool 1408, the robot 1402 retracts, rotates, and prepares the array end effector 1406 to retrieve additional work-pieces 1502 for further processing. Another robot 1412 having an array end effector positioned along a track 2002 prepares to retrieve the work-pieces 1502 from the processing tool 1408 as shown in FIG. 20.

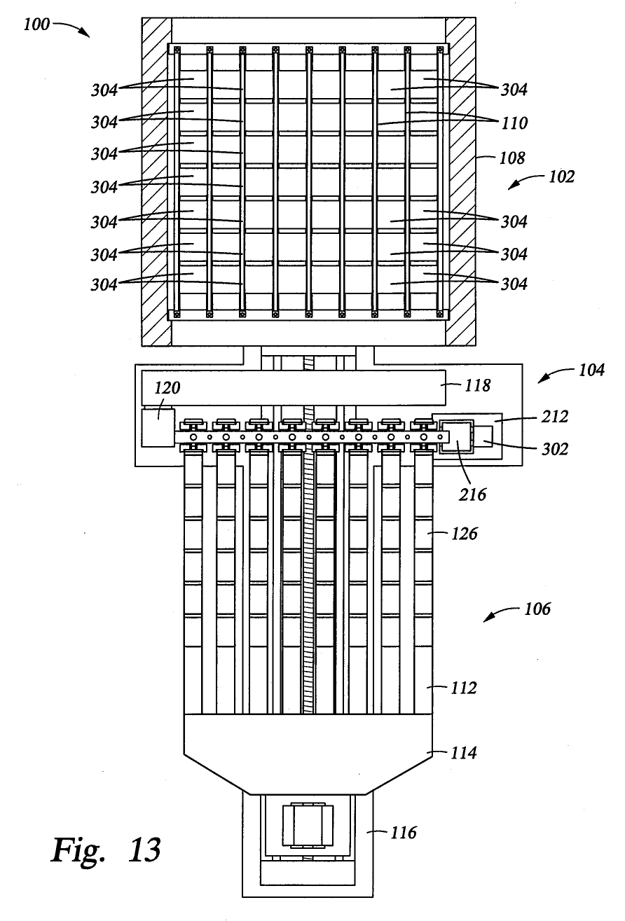

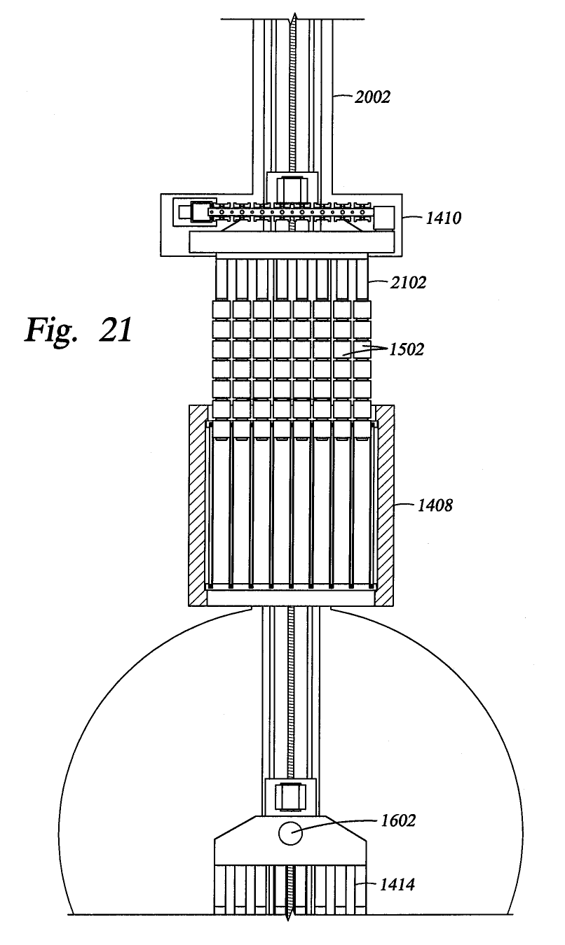

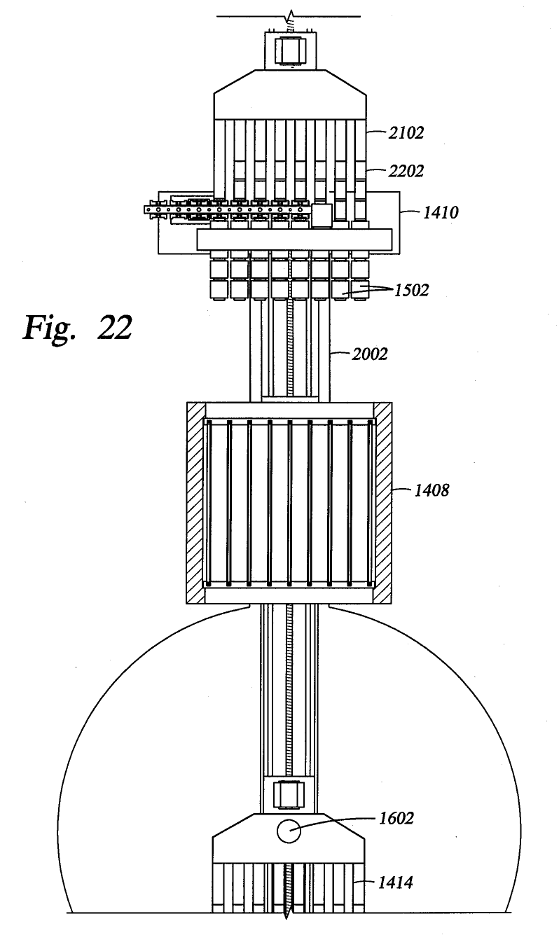

The robot 1412 extends the array end effector into the processing tool 1408 and retrieves the work-pieces 1502 as shown in FIG. 21. The work-pieces 1502 may be positioned in a plurality of slots 2202 (see FIG. 22) disposed on the plurality of fingers 2102 present on the array end effector of the robot 1412. The work-pieces 1502 may be unloaded from the array end effector of the robot 1412 by a parallel-to-stack unloading robot 1410. The unloading robot 1410 operates the same as the stack-to-parallel loader robot 104 discussed above in relation to FIGS. 1-13, except that the unloading robot 1410 retrieves the work-pieces from a parallel orientation and stacks the work-pieces vertically.

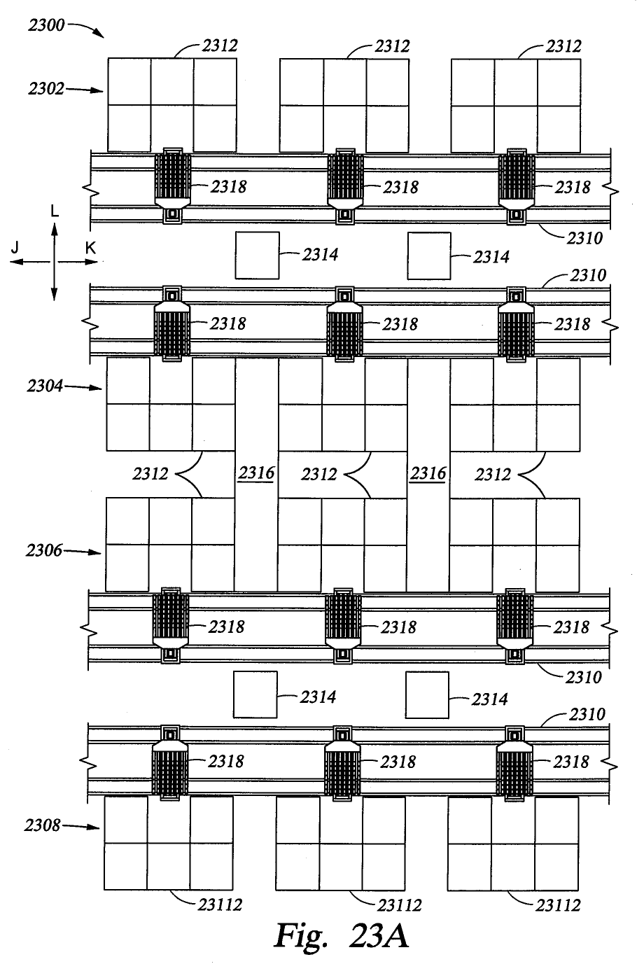

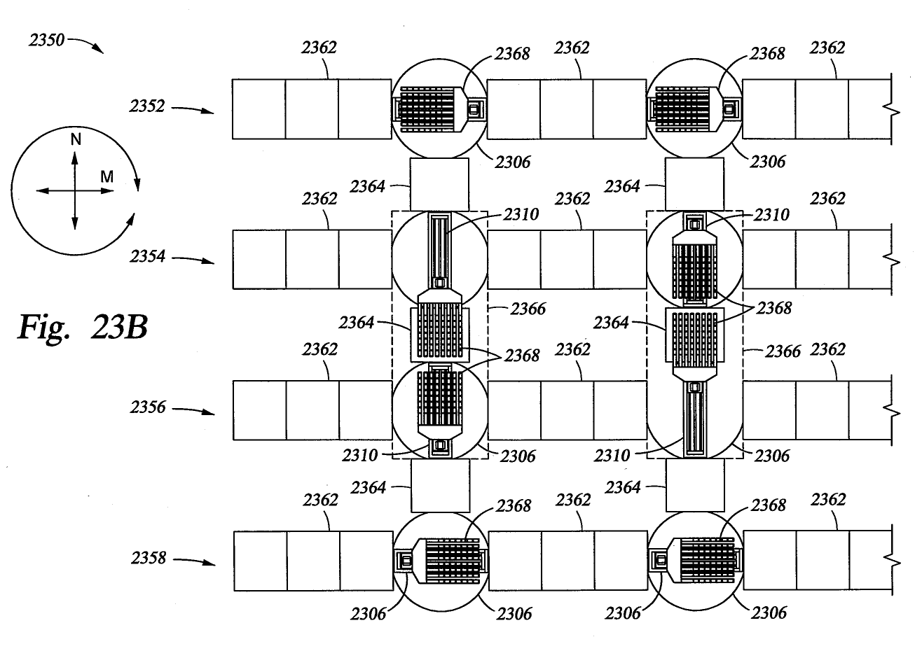

FIGS. 23A and 23B are schematic views of a plurality of processing tools coupled together in a FAB 2300, 2350. For a non-linearly arranged FAB 2300, the processing lines 2302, 2304, 2306, 2308 may be substantially identical with a plurality of processing tools 2312 arranged therein. Array end effectors 2318 may move along a common track 2310 for each processing line 2302, 2304, 2306, 2308 with each array end effector 2318 able to access multiple processing tools 2312. The array end effector 2318 may move either to the left as shown by arrow “J” or to the right as shown by arrow “K” along the track 2310 as shown by the array end effector 2318 in shadow. The array end effectors 2318 may also extend as shown by arrows “L” to access a processing tool 2312 or extend to access a buffer station 2314 to permit transfer of work-pieces between adjacent processing lines 2302, 2304, 2306, 2308. To transfer work-pieces to processing lines 2302, 2304, 2306, 2308 that are not adjacent or, in the case of processing lines 2304, 2306 that are facing opposite directions to each other, a stocker station 2316 may be used to transfer work-pieces. The stocker station 2316 may transfer work-pieces up and over to additional processing lines 2302, 2304, 2306, 2308 or permit transfer over distances greater than an array end effector 2318 may extend.

Similarly, for a linearly arranged FAB 2350, the processing lines 2352, 2354, 2356, 2358 may be substantially identical with a plurality of processing tools 2362 arranged therein. Array end effectors 2358 may move along a track 2360 with each array end effector 2368 able to access multiple processing tools 2362. The array end effector 2368 may move as shown by arrow “M” to access the processing tools 2362 or rotate and extend as shown by arrows “N” to a buffer station 2364 to permit transfer of work-pieces between adjacent processing lines 2352, 2354, 2356, 2358. To transfer work-pieces to processing lines 2352, 2354, 2356, 2358 that are not adjacent, a stocker station 2366 may be used to transfer work-pieces. The stocker station 2366 may transfer work-pieces up and over to additional processing lines 2352, 2354, 2356, 2358 or permit transfer over distances greater than an array end effector 2368 may extend.

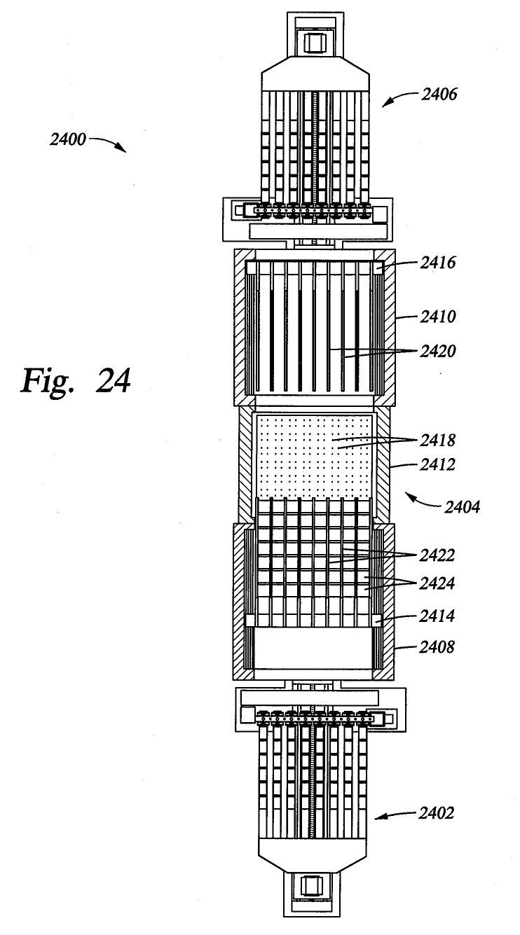

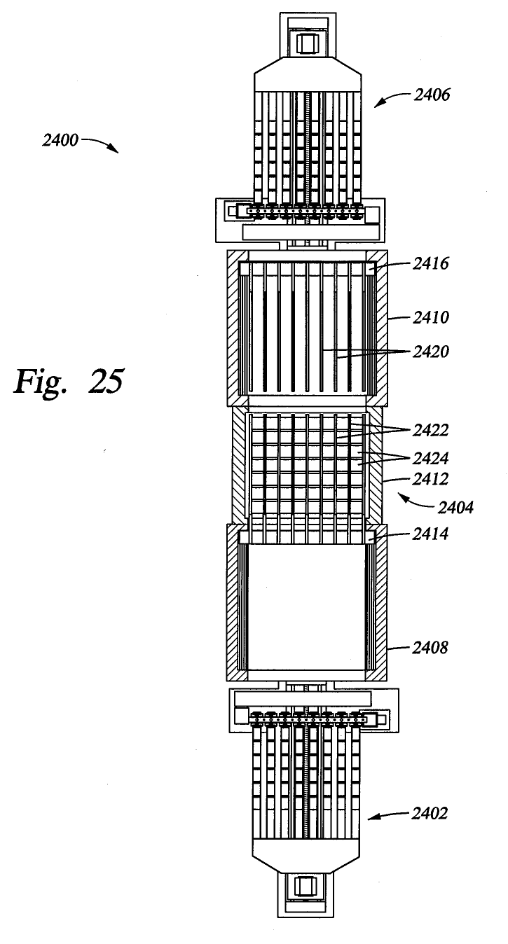

FIG. 24 is a top view of a parallel to parallel transfer arrangement 2400 for a processing tool 2404 according to one embodiment of the invention. The arrangement 2400 includes an array end effector 2402 that may insert a plurality of work-pieces 2424 into a load lock chamber 2408. The work-pieces 2424 may be received on receivers 2422 of an array end effector 2414 in the load lock chamber 2408. The array end effector 2414 may then extend from the load lock chamber 2408 into the processing chamber 2412. FIG. 25 is a top view of the processing tool of FIG. 24 with the array end effector 2414 extended into the processing chamber 2412. The processing chamber 2412 may be one or more processing chambers 2412 and may comprise CVD chambers, PVD chambers, etching chambers, cleaning chambers, etc.

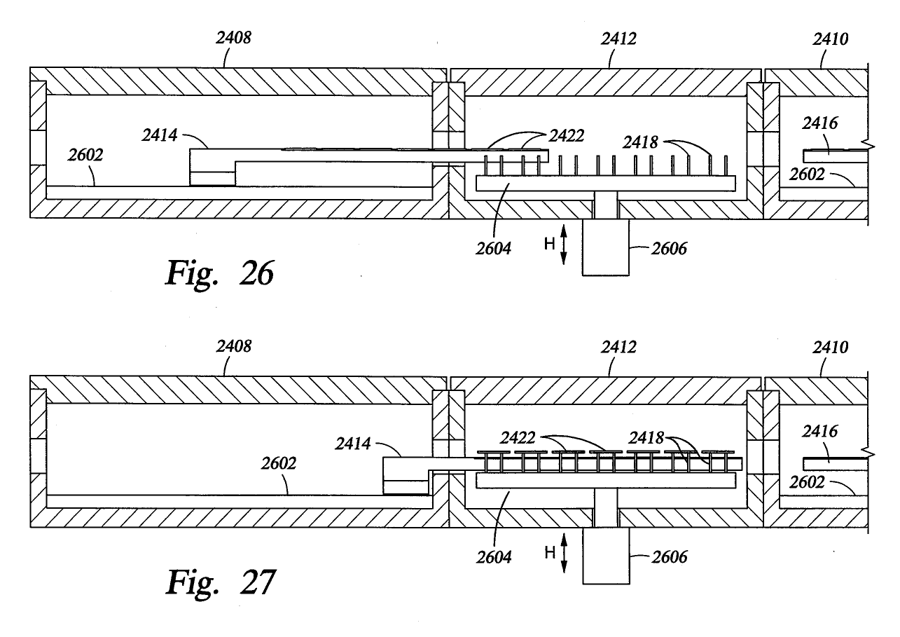

FIG. 26 is a cross sectional view of FIG. 25. Within the processing chamber 2412, a plurality of lift pins 2418 may be disposed. The lift pins 2418 may be disposed on a lift plate 2604. The lift pins 2418 may raise as shown by arrows “H” to meet the plurality of work-pieces 2424 to lift the work-pieces 2424 from the receivers 2422 of the array end effector 2414. In one embodiment, the lift pins 2418 may comprise about 4 lift pins 2418 per work-piece 2424. The lift pins 2418 may be disposed within the processing chamber 2412 such that the lift pins 2418 may be between the receivers 2422 of the array end effector 2414.

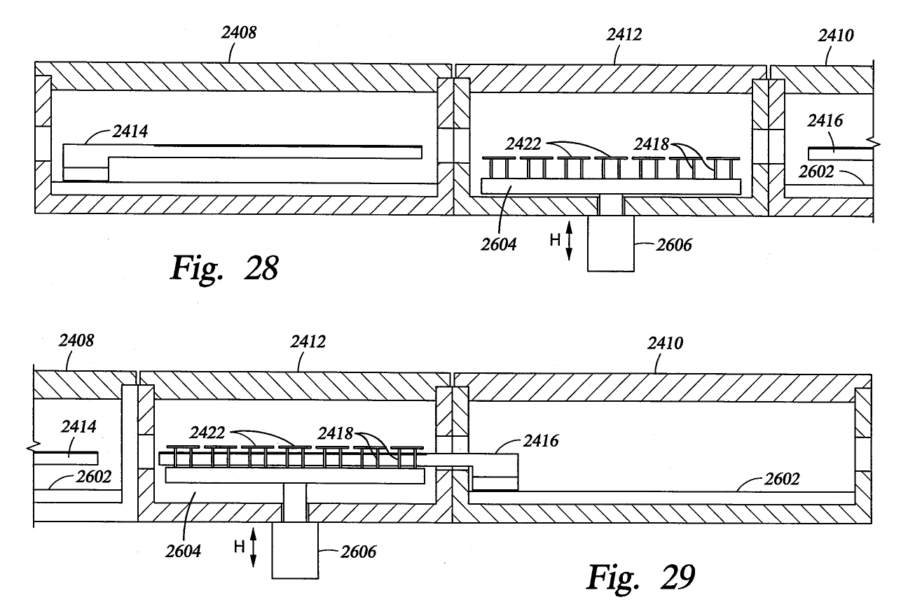

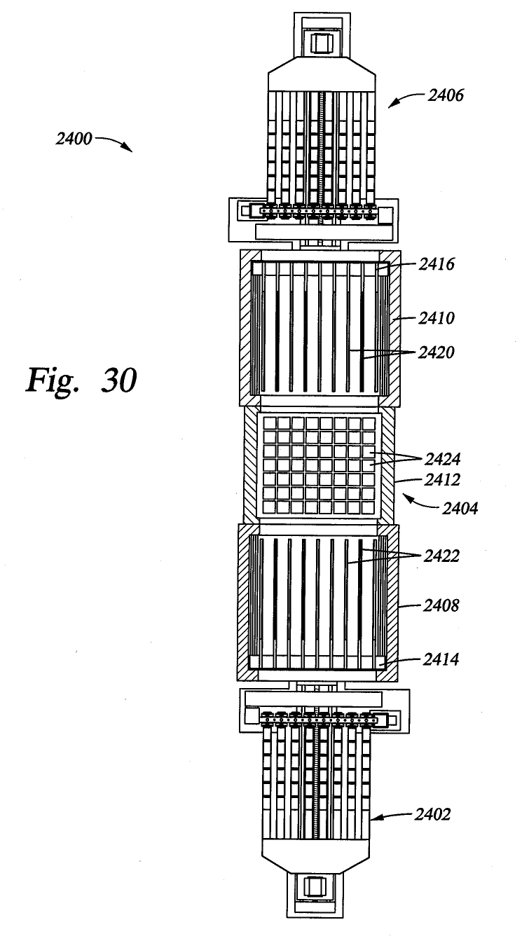

FIG. 27 is a cross sectional view of the processing tool of FIG. 24 with the array end effector extending into the processing chamber. After the lift pins 2418 raise the work-pieces 2424 from the array end effector 2414, the array end effector retracts from the processing chamber 2412 along a track 2602 (FIG. 28). FIG. 30 is a top view of the processing tool of FIG. 24 with a plurality of work-pieces inserted into the processing chamber. For clarity, the track is not shown within FIGS. 26-29 within the processing chamber 2412, but it is to be understood that the track 2602 may extend within the processing chamber 2412. If multiple processing chambers 2412 are present, the array end effector 2414 may extend along the track 2602 into multiple processing chambers 2412.

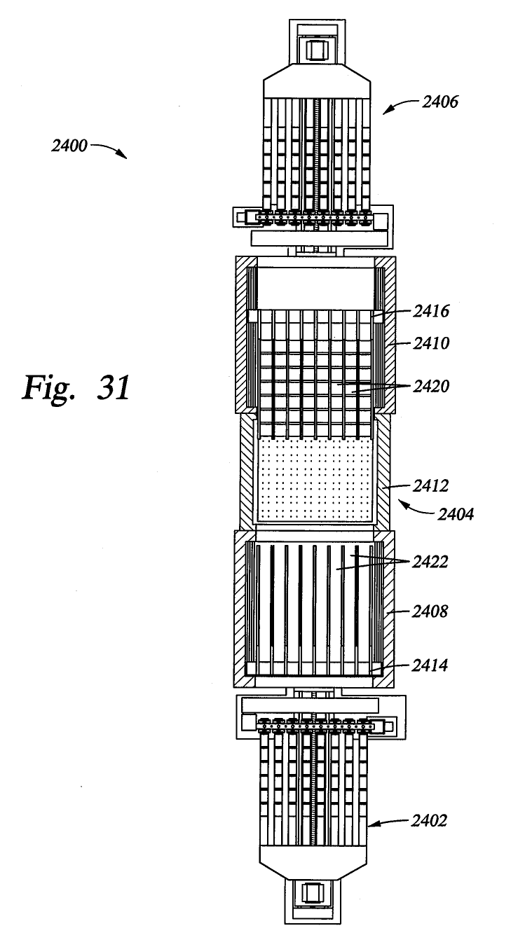

After processing, the work-pieces 2424 may be removed from the processing chamber 2412. FIG. 29 is a cross sectional view of the processing tool arrangement 2400 of FIG. 24 with another array end effector 2416 entered into the processing chamber 2412 to retrieve the work-pieces 2424. The array end effector 2416 may extend into the processing chamber 2412 from an unload lock chamber 2410. The array end effector 2416 may comprise a plurality of receivers 2420 for receiving the plurality of work-pieces 2424 from the processing chamber 2412. FIG. 31 is a top view of the processing tool of FIG. 24 with a plurality of work-pieces 2424 retrieved from the processing chamber 2412 into the unload lock chamber 2410. After the array end effector 2416 retrieves the work-pieces from the processing chamber 2412, the work-pieces 2424 may then be retrieved from the unload lock chamber by another array end effector 2406. The work-pieces may then be transferred to another processing tool or stored.

Transferring the work-pieces from one processing tool to another by maintaining the work-pieces in a parallel orientation may improve work-piece throughput. By storing the work-pieces in a vertical stack and then loading the work-pieces parallel across an array end effector, valuable space within a factory may be saved. Additionally, a great number of work-pieces may be loaded onto the array end effector for simultaneous processing within a processing tool. A parallel to parallel transfer of the work-pieces within a processing tool may permit multiple chambers to be coupled together within a processing tool. Thus, the present invention saves valuable floor space within a factory while providing a large work-piece throughput.

While the foregoing is directed to embodiments of the present invention, other and further embodiments of the invention may be devised without departing from the basic scope thereof, and the scope thereof is determined by the claims that follow.

1. An array to array photovoltaic work-piece transfer apparatus for array to array transferring of photovoltaic work-pieces between processing tools, comprising:
a robot coupled with a track extending between a plurality of processing tools, the robot having an axis of rotation; and
an array end effector connected to the robot, the array end effector having a plurality of fingers extending therefrom with each finger having one or more slots for disposing a work-piece thereon, the array end effector is capable of translation along the track, insertion into a first processing tool to retrieve an array of photovoltaic work-pieces, retraction along the track, rotation about the axis of rotation, and insertion into a second processing tool to dispose the array of photovoltaic work-pieces into the second processing tool.

2. The apparatus of claim 1, wherein the apparatus further comprises a buffer station for array to array transfer of an array of photovoltaic work-pieces to additional processing tools not directly accessible by the array end effector.

3. The apparatus of claim 1, wherein the first and second processing tools are arranged in a flow through orientation.

4. The apparatus of claim 1, wherein the array end effector is capable of holding a plurality of work-pieces thereon in substantially the same plane.

5. The apparatus of claim 1, wherein the robot is capable of extending the array end effector vertically along the robot axis of rotation.

6. The apparatus of claim 1, wherein the array end effector is substantially centrally disposed about the axis of rotation.

7. A method of array to array transferring a plurality of photovoltaic work-pieces, comprising:
extending an array end effector into a first processing tool, the array end effector having a plurality of slots for receiving the work-pieces;
retrieving a plurality of work-pieces from the first processing tool onto the array end effector, each work-piece disposed in a separate slot on the array end effector;
retracting the array end effector from the first processing tool;
rotating the array end effector; and
extending the array end effector into a second processing tool.

8. The method of claim 7, wherein the plurality of work-pieces are disposed on the array end effector within substantially the same plane across the array end effector once the plurality of work-pieces are received onto the array end effector.

9. The method of claim 7, wherein a robot extends the array end effector into the first and second processing tools, and wherein the robot rotates the array end effector about a robot axis of rotation.

10. The method of claim 9, wherein the robot axis of rotation corresponds to substantially the center of the array end effector.

11. The method of claim 7, wherein the retrieving further comprises:
raising the array end effector such that the plurality of work-pieces are lifted above a substrate support within the first processing tool.

12. The method of claim 7, further comprising:
lowering the array end effector after the array end effector is extended into the second processing tool, wherein as the array end effector is lowered, the plurality of work-pieces come to rest on a work-piece receiver while the array end effector continues to lower; and
extracting the array end effector from the second processing tool.

13. The method of claim 7, further comprising:
disposing the plurality of work-pieces in a buffer station prior to extending the array end effector into the second processing tool.

14. The method of claim 7, wherein array end effector is in separate planes while extending the array end effector into the first tool and retracting the array end effector from the first tool.

15. A method of transferring a plurality of photovoltaic work-pieces from a first processing tool to a second processing tool, comprising:
transferring the plurality of work-pieces from a processing chamber disposed within the first processing tool to a first load lock chamber disposed within the first processing tool;
extending an array end effector into the first load lock chamber, the array end effector having a plurality of slots for receiving the work-pieces;
retrieving a plurality of work-pieces from the first load lock chamber onto the array end effector, each work-piece disposed in a separate slot on the array end effector;
retracting the array end effector from the first load lock chamber;
rotating the array end effector; and
extending the array end effector into a second load lock chamber disposed in the second processing tool.

16. The method of claim 15, further comprising:
lowering the array end effector after the array end effector is extended into the second load lock chamber, wherein as the array end effector is lowered, the plurality of work-pieces come to rest on a substrate support while the array end effector continues to lower; and
extracting the array end effector from the second load lock chamber.

17. The method of claim 15, wherein the plurality of work-pieces are disposed on the array end effector within substantially the same plane across the array end effector once the plurality of work-pieces are retrieved onto the array end effector.

18. The method of claim 15, wherein a robot extends the array end effector into the first and second load lock chambers, and wherein the robot rotates the array end effector about a robot axis of rotation.

19. The method of claim 15, wherein array end effector is in separate planes while extending the array end effector into the first tool and retracting the array end effector from the first tool.

20. The method of claim 15, wherein the retrieving further comprises:
raising the array end effector such that the plurality of work-pieces are lifted above a substrate support within the first processing tool.
